(19) United States
(12) Patent Application Publication
(10) Pub. No.: US 2013/0067736 A1
(43) Pub. Date: Mar. 21, 2013

(54) PIN ADJUSTER FOR ELECTRONIC COMPONENT

(71) Applicants: KUO-CHAN PENG, PINGZHEN CITY (TW); CHING-FENG HSIEH, TAIPEI CITY (TW)

(72) Inventors: KUO-CHAN PENG, PINGZHEN CITY (TW); CHING-FENG HSIEH, TAIPEI CITY (TW)

(73) Assignees: ASKEY COMPUTER CORP.; ASKEY TECHNOLOGY (JIANGSU) LTD.

(21) Appl. No.: 13/278,200

(22) Filed: Oct. 21, 2011

(30) Foreign Application Priority Data
Sep. 16, 2011 (TW) 100133338

(51) Int. Cl. H05K 13/04

(52) U.S. Cl. 29/741

(57) ABSTRACT

A pin adjuster for electronic components adjusts and fixes pins of an electronic component while the electronic component is being installed on a circuit board such that the pins correspond in position to and connect to a plurality of contacts on the circuit board, respectively. The pin adjuster includes an insulating body and a plurality of channels. The channels each penetrate the insulating body and have an entry end and an exit end. The entry ends correspond in position to the pins of the electronic component, respectively, and the exit ends correspond in position to the contacts, respectively, such that the pins are adjusted and fixed in place by penetrating the channels, respectively. The pin adjuster enables the pins to be aligned with and connected to the contacts rapidly and precisely, thereby shortening the time taken to mount the electronic component on the circuit board and streamlining manual operation.

### CROSS-REFERENCE TO RELATED APPLICATION

This non-provisional application claims priority under 35 U.S.C. §119(a) on Patent Application No(s). 100133338 filed in Taiwan, R.O.C. on Sep. 16, 2011, the entire contents of which are hereby incorporated by reference.

### FIELD OF TECHNOLOGY

The present invention relates to a pin adjuster for electronic component, and more particularly to a pin adjuster for adjusting and holding pins of an electronic component to positions corresponding to contacts on a circuit board.

### BACKGROUND

Generally, various common electronic components are mounted and electrically connected to a circuit board by soldering pins on the electronic components to corresponding contacts on the circuit board. Such electronic components may include but not limited to resistors, capacitors, transistors, transmitter modules, receiver modules, and transceiver modules. These modules have pins protruded from a main body thereof for soldering and electrically connecting to the contacts on the circuit board. The contacts are usually provided on the circuit board according to predetermined layouts, and have very small spaces left between them. Therefore, before the electronic components are soldered to the circuit board, the pins on the electronic components must be adjusted and/or trimmed, so that the pins are located corresponding to and aligned with the contacts pre-arranged on the circuit board. Moreover, the pins must be cut to have suitable lengths to avoid errors in electrical connection or short-circuit.

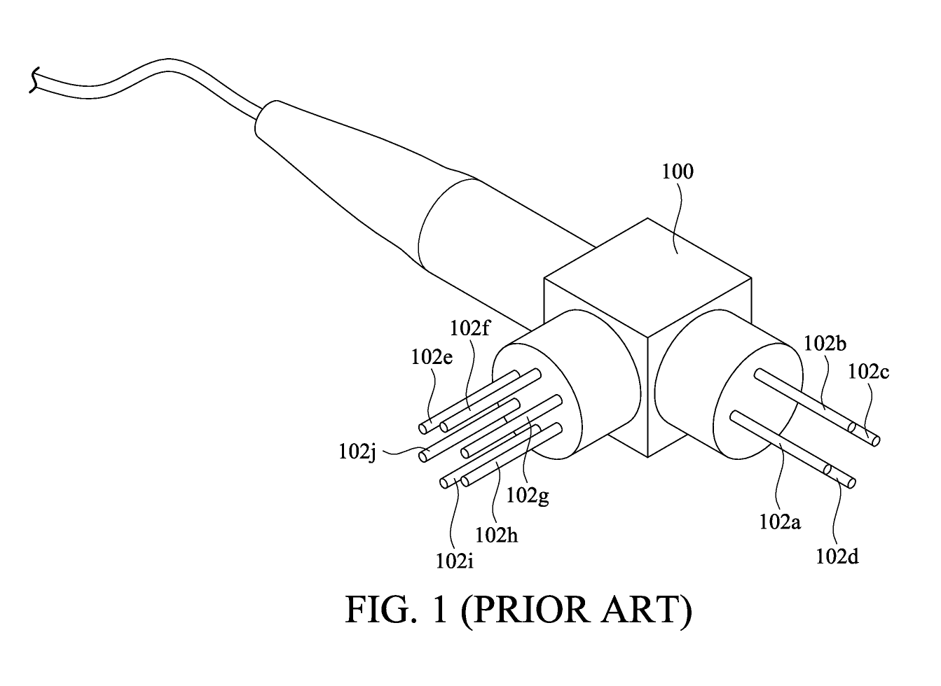

Some electronic components might have three or more pins provided thereon. These pins are usually arranged on one side of the electronic components and are spatially staggered to thereby cause difficulty in aligning the pins with the contacts on the circuit board. Please refer to FIG. 1 that shows an example of an electronic component 100 configured as a bi-directional optical sub-assembly (BOSA). The BOSA includes a transmitter composed of a laser diode (LD) and a receiver composed of a photodiode (PD). The laser diode for the transmitter has four pins 102a-102d, which are arranged on an end surface of the transmitter as four vertexes of a quadrilateral. The photodiode for the receiver has six pins 102e-102j, which are arranged on an end surface of the receiver as six vertexes of a hexagon. Since these pins 102a-102j are not arranged on the end surfaces of the transmitter and receiver in a manner to be coplanar with surfaces of the circuit board, the pins are spaced from the circuit board surfaces by different distances. Thus, before mounting and soldering the electronic component 100 to the circuit board, the pins 102a-102j of the electronic component 100 must be bent for them to align and contact with the contacts on the circuit board. Meanwhile, the pins are made of a metal material and are subject to bending and deformation in the procedures of pin adjusting, mounting and soldering to result in confusion in manual operation or defective products.

Thus, according to conventional technical means, before the BOSA can be mounted and soldered to the circuit board, the pins on the BOSA must first be manually adjusted and trimmed one by one for them to align with the contacts on the circuit board. Furthermore, due to the miniaturization of electronic components, circuits are arranged on the circuit boards in a high density, which results in very small spaces between contacts. Thus, it is very difficult and time-consuming to adjust and trim the pins through manual operation. These conditions also form hindrances to mass production of the electronic components on production lines at controlled time cost.

### SUMMARY

A primary object of the present invention is to provide a pin adjuster for electronic component, so that pins on an electronic component can be quickly and correctly aligned with and connected to contacts on a circuit board.

Another object of the present invention is to provide a pin adjuster for electronic component, so that an electronic component can be mounted to a circuit board with largely reduced time and labor.

To achieve the above and other objects, the pin adjuster for electronic component according to the present invention is used as an aid for mounting an electronic component having a plurality of pins to a circuit board having a plurality of contacts, and includes an insulating body having a plurality of channels formed on thereon. The channels axially extend through the insulating body and respectively have an inlet end and an outlet end. The inlet ends are arranged corresponding to the pins on the electronic component, and the outlet ends are arranged corresponding to the contacts on the circuit board. When the pins are correspondingly extended through the channels via the inlet ends, the pins finally projected from the outlet ends are adjusted and held to positions corresponding to the contacts, and can therefore be conveniently connected to the contacts.

In the pin adjuster of the present invention, at least one of the channels is internally formed with a bend guiding section for bending the pin extended therethrough before the pin is projected from the outlet end of the channel.

According to an embodiment of the present invention, at least one of the channels is internally formed with two bend guiding sections. The pin extended through the channel having two bend guiding sections is bent by a first one of the bend guiding sections to incline downward from a horizontal position by a predetermined length and then bent again by a second one of the bend guiding sections to a horizontal position.

The circuit board includes a first surface and an opposite second surface, and the contacts of the circuit board are provided on both of the first and the second surface. And, according to an embodiment of the present invention, the outlet ends of the channels are arranged in two straight lines to correspond to the contacts on the first and the second surface of the circuit board.

According to an embodiment of the present invention, the channels on the pin adjuster are four in number, and the outlet ends of three of the four channels are arranged at positions corresponding to the contacts on the first surface of the circuit board while the outlet end of the fourth channel is arranged at a position corresponding to the contact on the second surface of the circuit board. Alternatively, according to another embodiment of the present invention, the channels on the pin adjuster are six in number, and the outlet ends of three of the six channels are arranged at positions corresponding to the contacts on the first surface of the circuit board while the outlet ends of the other three channels are arranged at positions corresponding to the contacts on the second surface of the circuit board.

The pin adjuster according to the present invention can be mounted on the electronic component before the latter is mounted and soldered to the circuit board, so as to adjust and hold the pins of the electronic component to desired positions. That is, the electronic component with the pin adjuster of the present invention mounted thereon can have pins correctly aligned with the contacts on the circuit board, enabling the pins to be quickly connected to the contacts with largely reduced time and labor. Further, the pin adjuster also protects the pins against undesired deformation in the mounting process and reduces the probability of defective products caused by improper manual operation during connection of the electronic component to the circuit board.

### BRIEF DESCRIPTION

The structure and the technical means adopted by the present invention to achieve the above and other objects can be best understood by referring to the following detailed description of the preferred embodiments and the accompanying drawings, wherein

FIG. 1 shows an example of an electronic component;

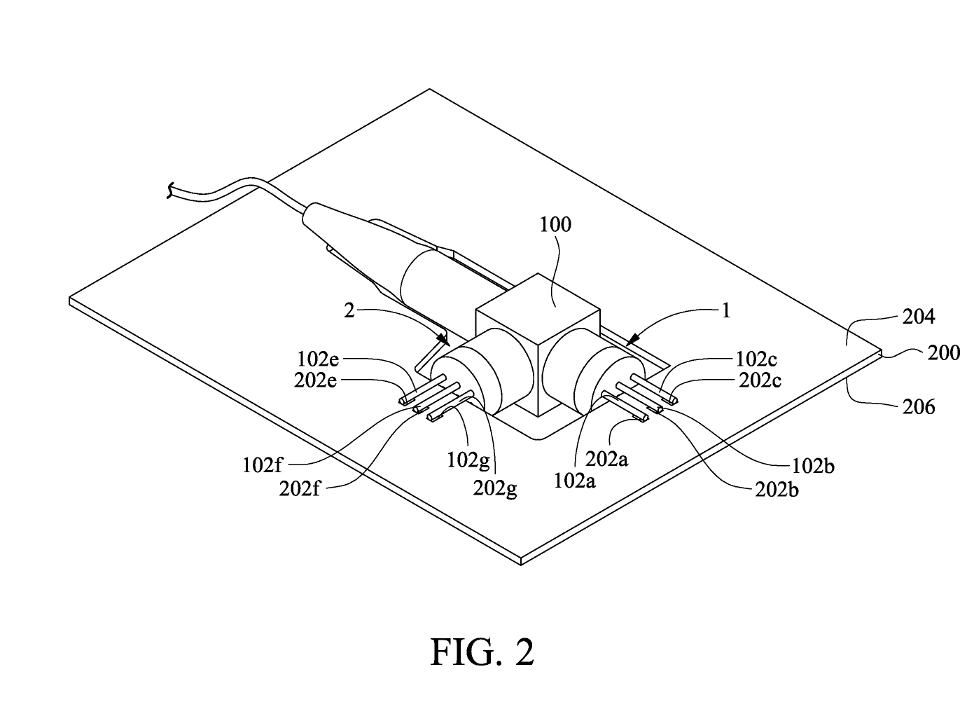

FIG. 2 shows the connection of an electronic component to a circuit board with the aid of pin adjusters according to the present invention, being viewed from a first surface of the circuit board;

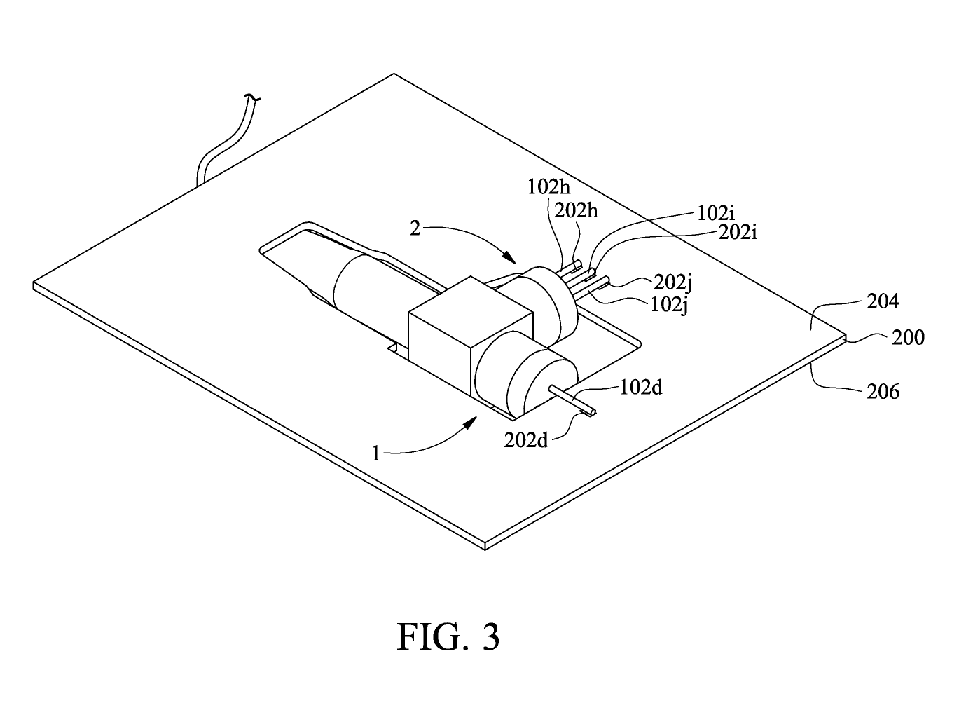

FIG. 3 shows the connection of an electronic component to a circuit board with the aid of pin adjusters according to the present invention, being viewed from an opposite second surface of the circuit board;

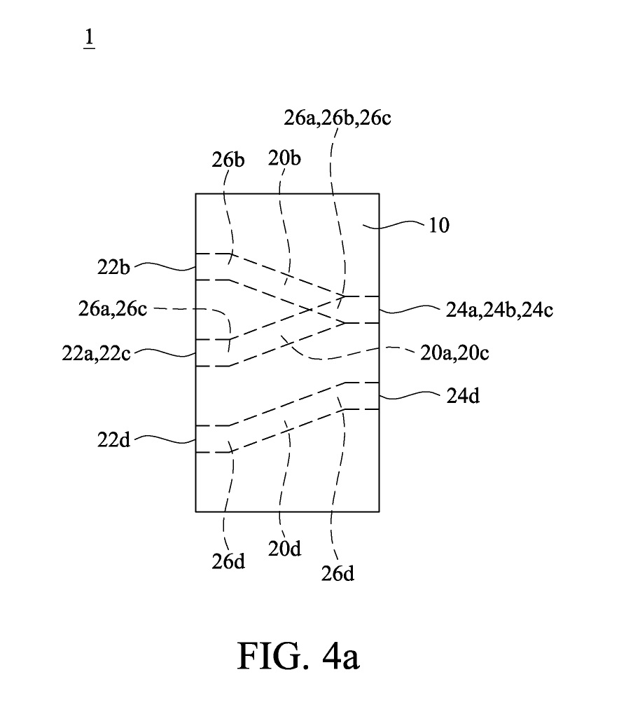

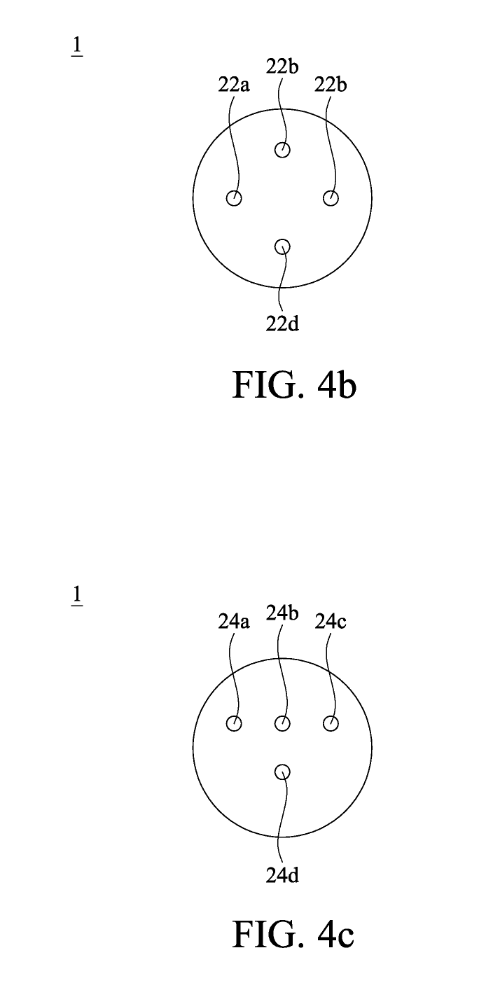

FIGS. 4a, 4b and 4c are sectional side view, inlet end view, and outlet end view, respectively, of a pin adjuster according to a first embodiment of the present invention for use with a transmitter on an electronic component;

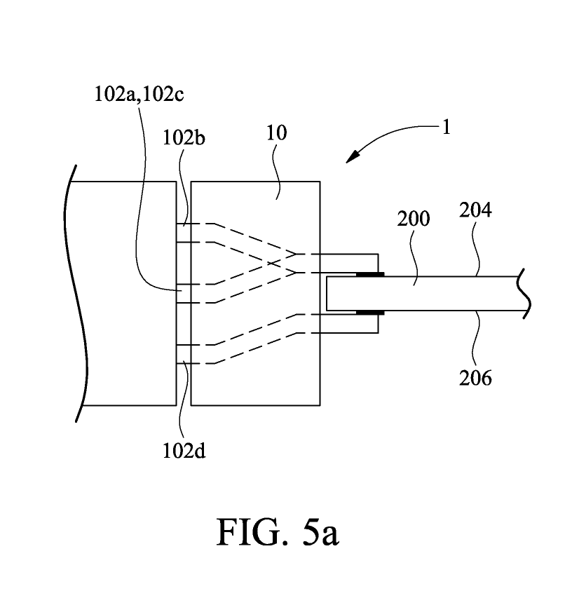

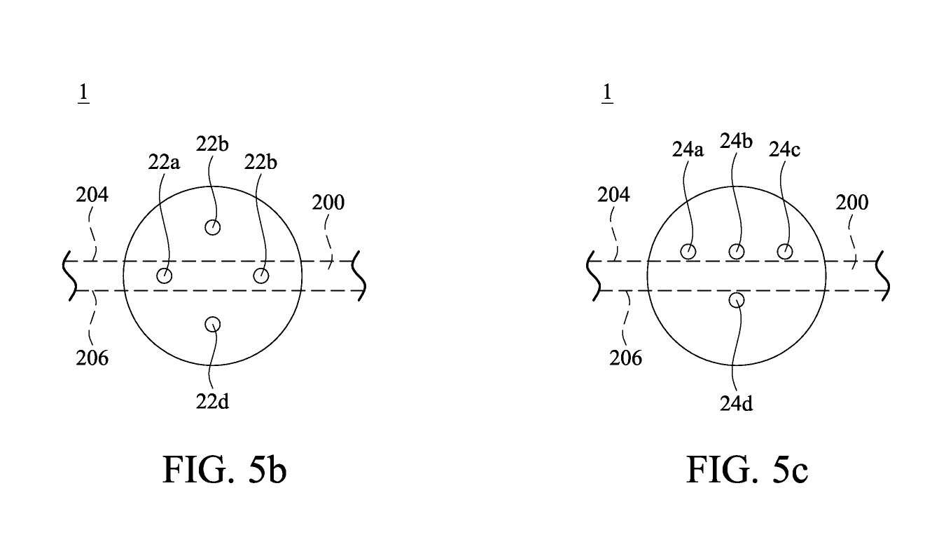

FIGS. 5a, 5b and 5c are sectional side view, inlet end view, and outlet end view, respectively, showing the pin adjuster according to the first embodiment of the present invention is mounted to a transmitter on an electronic component for pins of the transmitter to be quickly and correctly electrically connected to contacts on a circuit board;

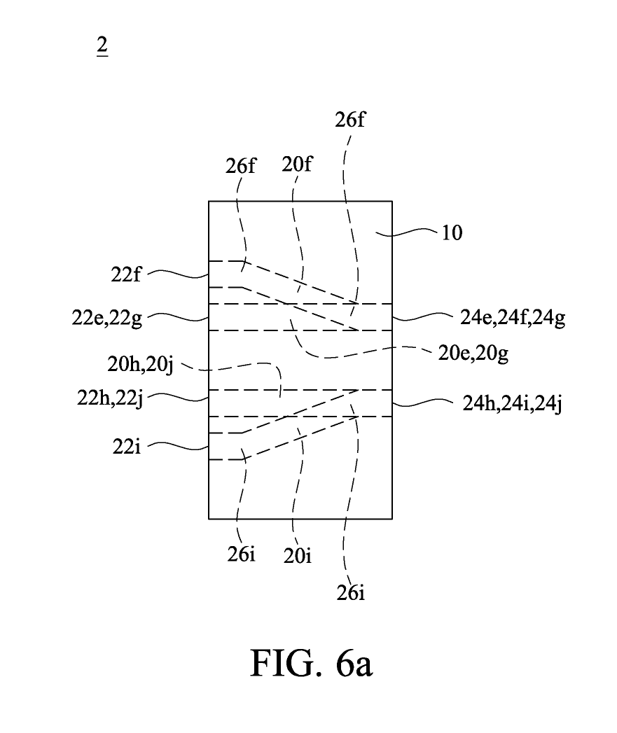

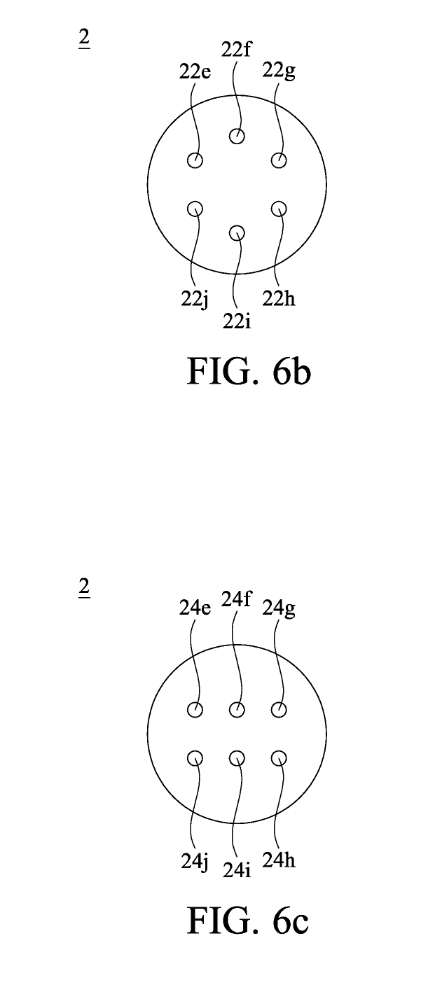

FIGS. 6a, 6b and 6c are sectional side view, inlet end view, and outlet end view, respectively, of a pin adjuster according to a second embodiment of the present invention for use with a receiver on an electronic component; and

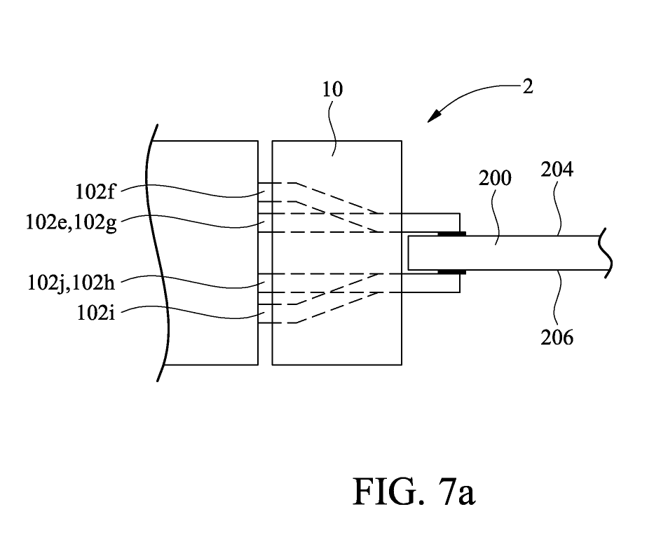

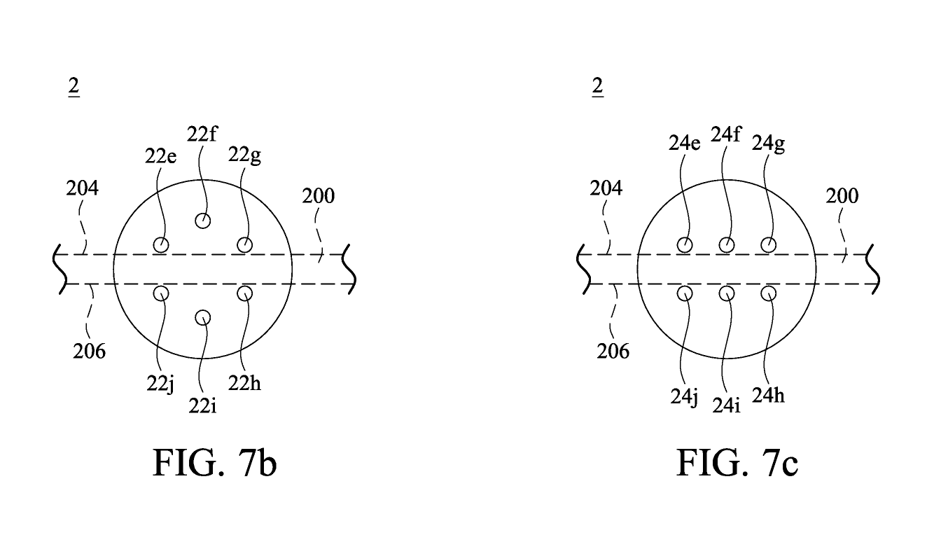

FIGS. 7a, 7b and 7c are sectional side view, inlet end view, and outlet end view, respectively, showing the pin adjuster according to the second embodiment of the present invention is mounted to a receiver on an electronic component for pins of the receiver to be quickly and correctly electrically connected to contacts on a circuit board.

### DETAILED DESCRIPTION

The present invention will now be described with some preferred embodiments thereof and with reference to the accompanying drawings. For the purpose of easy to understand, elements that are the same in the preferred embodiments are denoted by the same reference numerals.

Please refer to FIGS. 2 and 3 that are perspective views viewed from a first surface 204 and an opposite second surface 206 of a circuit board 200, respectively, showing the connection of an electronic component 100 to the circuit board 200 with the aid of pin adjusters 1, 2 according to the present invention. As shown, the pin adjusters 1, 2 are configured for adjusting and holding a plurality of pins 102a-102j of the electronic component 100 in place, so that the pins 102a-102j can be conveniently and correctly connected to contacts 202a-202j on the circuit board 200. Herein, the present invention is described with the electronic component 100 being a bi-directional optical sub-assembly (BOSA) having four pins 102a-102d provided on an end surface of a transmitter thereof and six pins 102e-102j provided on an end surface of a receiver thereof, as shown in FIG. 1. However, it is understood the pin adjuster of the present invention can be applied to various types of electronic components 100 having multiple pins without being limited to the use with a BOSA.

Please refer to FIGS. 4a to 4c, in which a pin adjuster 1 according to a first embodiment of the present invention for use with a transmitter on an electronic component is shown. As shown, the pin adjuster 1 includes an insulating body 10, on which a plurality of channels 20a-20d is formed. The channels 20a-20d are axially extended through the insulating body 10, and respectively have an inlet end 22a-22d and an outlet end 24a-24d. Please refer to FIGS. 4a to 4c along with FIGS. 1 to 3. The inlet ends 22a-22d on the insulating body 10 are arranged corresponding to the pins 102a-102d on the transmitter of the electronic component 100, and the outlet ends 24a-24d on the insulating body 10 are arranged corresponding to the contacts 202a-202d on the circuit board 200. By extending the pins 102a-102d through the channels 20a-20d via the inlet ends 22a-22d, the pins 102a-102d projected from the outlet ends 24a-24d are adjusted and held to positions corresponding to the contacts 202a-202d and can therefore be conveniently connected thereto.

FIGS. 5a-5c are sectional side view, inlet end view, and outlet end view, respectively, showing the pin adjuster 1 according to the first embodiment of the present invention is mounted to the transmitter on the electronic component 100 for the pins 102a-102d of the transmitter to electrically connect to the contacts 202a-202d on the circuit board 200. Please refer to FIGS. 5a-5c along with FIG. 1. Here, the illustrated electronic component 100 is a BOSA, the transmitter of which has four pins 102a, 102b, 102c, 102d arranged on an end surface thereof as four vertexes of a quadrilateral. It is noted three of the four pins, i.e. pins 102a, 102b and 102c are to be correspondingly connected to the contacts 202a, 202b and 202c on the first surface 204 of the circuit board 200 while the fourth pin 102d is to be connected to the contact 202d on the second surface 206 of the circuit board 200. Therefore, the pin adjuster 1 for use with the transmitter of the electronic component 100 as a BOSA can have four channels 20a-20d formed on the insulating body 10. More specifically, three of the four channels, i.e. channels 20a, 20b and 20c, have their inlet ends 22a, 22b and 22c arranged corresponding to the pins 102a, 102b and 102c on the end surface of the transmitter of the electronic component 100. Please refer to FIGS. 5a-5c along with FIG. 2. The outlet ends 24a, 24b and 24c of the channels 20a, 20b and 20c are arranged corresponding to the contacts 202a, 202b and 202c on the first surface 204 of the circuit board 200. Meanwhile, please also refer to FIGS. 5a-5c along with FIG. 3. The inlet end 22d of the fourth channel 20d is arranged corresponding to the pin 102d on the end surface of the transmitter of the electronic component 100 while the outlet end 24d of the channel 20d is arranged corresponding to the contact 202d on the second surface 206 of the circuit board 200.

Please refer to FIGS. 5a-5c along with FIGS. 4a-4c. The channels 20a-20d respectively include two bend guiding sections 26a-26d. It is known the pins 102a, 102b, 102c on the electronic component 100 are not arranged in a straight line. By extending the pins 102a, 102b and 102c into the channels 20a, 20b and 20c via the inlet ends 22a, 22b and 22c, the pins 102a, 102b and 102c will pass a first one of the two bend guiding sections 26a, 26b and 26c, respectively, and are bent to incline downward from an original horizontal position by a predetermined distance. Then, the bent pins 102a, 102b and 102c further pass the second bend guiding section 26a, 26b and 26c, respectively, and are bent again to a horizontal position to project from the outlet end 24a, 24b and 24c. The pins 102a, 102b and 102c projected from the insulating body 1 via the outlet end 24a, 24b and 24c are now arranged in a straight line within a common plane parallel with the first surface 204 of the circuit board 200 to correspond to the contacts 202a, 202b and 202c. That is, by using the pin adjuster 1 according to the first embodiment of the present invention, the pins 102a, 102b and 102c extended through the insulating body 10 via the channels 20a, 20b and 20c and projected from the outlet end 24a, 24b and 24c are now aligned with the contacts 202a, 202b and 202c, as shown in FIG. 2. Then, the pins 102a, 102b and 102c can be soldered and electrically connected to contacts 202a-202c on the circuit board 200. Meanwhile, the fourth pin 102d on the end surface of the transmitter of the electronic component 100 is spaced from the contact 202d on the second surface 206 of the circuit board 200 by a distance. By extending the pin 102d into the channel 20d via the inlet end 22d, the pin 102d will pass the two bend guiding sections 26d and is bent twice, so that the pin 102d finally projected from the outlet end 24d is aligned with the contact 202d, as shown in FIG. 3. Thereafter, the pin 102d can be soldered and electrically connected to the contact 202d on the circuit board 200.

FIGS. 6a to 6c show a pin adjuster 2 according to a second embodiment of the present invention for use with a receiver on an electronic component as a BOSA. Please refer to FIGS. 6a to 6c along with FIGS. 1 to 3. As shown, unlike the pin adjuster 1 of the first embodiment, the pin adjuster 2 is configured for connecting the pins 102e-102j of the receiver on the electronic component 100 to the contacts 202e-202j on the circuit board 200. The pins 102e-102j are arranged on the end surface of the receiver as six vertexes of a hexagon. Therefore, an insulating body 10 of the pin adjuster 2 is correspondingly provided with six channels 20e-20j, which respectively have an inlet end 22e-22j corresponding to the pins 102e-102j on the receiver of the electronic component 100 and an outlet end 24e-24j corresponding to the contacts 202e-202j on the circuit board 200. By extending the pins 102e-102j through the channels 20e-20j via the inlet ends 22e-22j, the pins 102e-102j projected from the outlet ends 24e-24j are adjusted and held to positions corresponding to the contacts 202e-202j and can therefore be conveniently connected thereto.

FIGS. 7a-7c are sectional side view, inlet end view, and outlet end view, respectively, showing the pin adjuster 2 according to the second embodiment of the present invention is mounted to the receiver on the electronic component 100 for the pins 102e-102j of the receiver to electrically connect to the contacts 202e-202j on the circuit board 200. Please refer to FIGS. 7a-7c along with FIGS. 1 to 3. Here, the illustrated electronic component 100 is a BOSA, the receiver of which has six pins 102e-102j arranged on the end surface thereof as six vertexes of a hexagon. It is noted three of the six pins, i.e. pins 102e, 102f and 102g are to be correspondingly connected to the contacts 202e, 202f and 202g on the first surface 204 of the circuit board 200 while the other three pins 102h, 102i and 102j are to be correspondingly connected to the contacts 202h, 202i and 202j on the second surface 206 of the circuit board 200. Therefore, three of the six channels formed on the insulating body 10 of the pin adjuster 2, i.e. channels 20e, 20f and 20g, have their inlet ends 22e, 22f and 22g arranged corresponding to the pins 102e, 102f and 102g on the end surface of the receiver of the electronic component 100 and their outlet ends 24e, 24f and 24g arranged corresponding to the contacts 202e, 202f and 202g on the first surface 204 of the circuit board 200. Meanwhile, the other three channels 20h, 20i and 20j have their inlet ends 22h, 22i and 22j arranged corresponding to the pins 102h, 102i and 102j on the end surface of the receiver of the electronic component 100 and their outlet ends 24h, 24i and 24j arranged corresponding to the contacts 202h, 202i and 202j on the second surface 206 of the circuit board 200.

As can be seen in FIGS. 1 to 3, on the end surface of the receiver of the electronic component 100, the pins 102e and 102g are originally located at positions aligned with the contacts 202e and 202g, respectively, and the pins 102h and 102j are originally located at positions aligned with the contacts 202h and 202j, respectively. Therefore, in the second embodiment, the channels 20e, 20h and the channels 20h, 20j corresponding to the pins 102e, 102g and the pins 102h, 102j, respectively, are straight channels extended through the insulating body 10, as can be seen from FIGS. 6a-6c and FIGS. 7a-7c. That is, only the channels 20f, 20i are respectively internally formed with two bend guiding sections 26f, 26i. Therefore, when the pins 102e-102j are correspondingly extended into the channels 20e-20j via the inlet ends 22e-22j, only the pins 102f, 102i are bent while all other pins 102e, 102g, 102h, 102j are just straightly extended through the channels 20e, 20g, 20h, 20j. The pins 102e-102j finally projected from the outlet ends 24e-24j are now adjusted and held in place, and are arranged in two straight lines, as shown in FIG. 7c, to align with the contacts 202e-202g and the contacts 202h-202j, respectively, as shown in FIGS. 2 and 3. Thereafter, the pins 102e-102j can be conveniently soldered and electrically connected to the contacts 202e-202j on the circuit board 200.

Therefore, before mounting an electronic component to a circuit board, an operator may first connect the pin adjusters 1, 2 according to the first and second embodiments of the present invention to the pins of the electronic component, so that the pins can be easily adjusted and held in place to align with contacts on the circuit board. The electronic component with the pin adjusters 1, 2 connected to the pins thereof can be quickly and correctly aligned with and connected to the corresponding contacts on the circuit board at largely reduced time and labor. The pin adjusters of the present invention also protect the pins of the electronic component against undesired deformation in the mounting process, and reduce the probability of defective products caused by improper manual operation.

The present invention has been described with some preferred embodiments thereof and it is understood that many changes and modifications in the described embodiments can be carried out without departing from the scope and the spirit of the invention that is intended to be limited only by the appended claims.

1. A pin adjuster for an electronic component, the pin adjuster being coupled to the electronic component such that the pin adjuster and the electronic component are jointly disposed on a circuit board, the electronic component having a plurality of pins, and the circuit board having a plurality of contacts, comprising:
an insulating body; and
a plurality of channels being formed on the insulating body to axially extend through the insulating body and respectively having an inlet end and an outlet end, the inlet end being arranged corresponding to the plurality of pins on the electronic component, and the outlet end being arranged corresponding to the plurality of contacts on the circuit board;
wherein at least one channel of the plurality of channels is internally formed with a bend guiding section for bending a pin of the plurality of pins extended therethrough before the pin is projected from the outlet end of the at least one channel;
wherein, when the plurality of pins are correspondingly extended through the plurality of channels via the inlet end, the plurality of pins projected from the outlet end are adjusted and held to positions corresponding to the plurality of contacts and are conveniently connected thereto.

2. (canceled)

3. The pin adjuster for the electronic component as claimed in claim 1, wherein at least one channel of the channels is internally formed with two bend guiding sections, whereby the pin extended through the at least one channel having two bend guiding sections is bent by a first one of the bend guiding sections to incline downward from a horizontal position by a predetermined length and then bent again by a second one of the bend guiding sections to a horizontal position.

4. The pin adjuster for electronic component as claimed in claim 1, wherein the circuit board has a first surface and an opposite second surface, the plurality of contacts being provided on both of the first and the second surface, and the outlet end of the plurality of channels being arranged in two straight lines corresponding to the plurality of contacts on the first and the second surface of the circuit board.

5. The pin adjuster for electronic component as claimed in claim 1, wherein the circuit board has a first surface and an opposite second surface, the plurality of contacts being provided on both of the first and the second surface, and the outlet end of the plurality of channels being arranged in two straight lines corresponding to the plurality of contacts on the first and the second surface of the circuit board.

6. The pin adjuster for electronic component as claimed in claim 3, wherein the circuit board has a first surface and an opposite second surface, the plurality of contacts being provided on both of the first and the second surface, and the outlet end of the plurality of channels being arranged in two straight lines corresponding to the plurality of contacts on the first and the second surface of the circuit board.

7. The pin adjuster for electronic component as claimed in claim 4, wherein the channels are four in number, and the outlet ends of three of the four channels being arranged at positions corresponding to the contacts on the first surface of the circuit board while the outlet end of the fourth channel being arranged at a position corresponding to the contact on the second surface of the circuit board.

8. The pin adjuster for electronic component as claimed in claim 5, wherein the channels are four in number, and the outlet ends of three of the four channels being arranged at positions corresponding to the contacts on the first surface of the circuit board while the outlet end of the fourth channel being arranged at a position corresponding to the contact on the second surface of the circuit board.

9. The pin adjuster for electronic component as claimed in claim 6, wherein the channels are four in number, and the outlet ends of three of the four channels being arranged at positions corresponding to the contacts on the first surface of the circuit board while the outlet end of the fourth channel being arranged at a position corresponding to the contact on the second surface of the circuit board.

10. The pin adjuster for electronic component as claimed in claim 4, wherein the plurality of channels are six in number, and the outlet end of three of the six channels being arranged at positions corresponding to the plurality of contacts on the first surface of the circuit board while the outlet end of the other three channels being arranged at positions corresponding to the plurality of contacts on the second surface of the circuit board.

11. The pin adjuster for electronic component as claimed in claim 5, wherein the plurality of channels are six in number, and the outlet end of three of the six channels being arranged at positions corresponding to the plurality of contacts on the first surface of the circuit board while the outlet end of the other three channels being arranged at positions corresponding to the plurality of contacts on the second surface of the circuit board.

12. The pin adjuster for electronic component as claimed in claim 6, wherein the plurality of channels are six in number, and the outlet end of three of the six channels being arranged at positions corresponding to the plurality of contacts on the first surface of the circuit board while the outlet end of the other three channels being arranged at positions corresponding to the plurality of contacts on the second surface of the circuit board.
